(19) United States
(12) Patent Application Publication
(10) Pub. No.: US 2012/0171472 A1
(43) Pub. Date: Jul. 5, 2012

(54) COATED ARTICLE AND METHOD FOR MAKING SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); JIA HUANG, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/164,270

(22) Filed: Jun. 20, 2011

(30) Foreign Application Priority Data
Dec. 30, 2010 (CN) 201010616252.9

(51) Int. Cl. B32B 9/04; B32B 18/00; C09D 5/00; B32B 5/00; C23C 14/35; B41M 5/26; B32B 17/06; B32B 15/04

(52) U.S. Cl. 428/336; 428/432; 428/446; 428/472; 204/192.15; 204/192.14; 252/583

(57) ABSTRACT

A coated article is provided. The coated article includes a substrate and a thermochromic layer formed on the substrate. The thermochromic layer is a vanadium dioxide layer co-doped with M and R. M comprises one or more elements selected from a group consisting of titanium, niobium, molybdenum and tungsten; R comprises one or more elements selected from a group consisting of rhodium, palladium and ruthenium. The thermochromic temperature of the thermochromic layer is reduced by doping M and R. A method for making the coated article is also described there.

### CROSS-REFERENCE TO RELATED APPLICATIONS

The present application is related to co-pending U.S. patent applications (Attorney Docket No. US35753), entitled “COATED ARTICLE AND METHOD FOR MAKING THE SAME”, by Zhang et al. These applications have the same assignee as the present application and have been concurrently filed herewith. The above-identified applications are incorporated herein by reference.

### BACKGROUND

1. Technical Field

The present disclosure relates to coated articles, particularly to coated articles with thermochromic property and a method for making the coated articles.

2. Description of Related Art

Vanadium dioxide (VO₂) materials have attracted much attention due to its thermochromic property. It is known that vanadium dioxide has a switching temperature T_{c} in the region of 68° C. Vanadium dioxide has high transmission properties of infrared light when the temperature is higher than the switching temperature T_{c}, while it has high reflection properties of infrared light when the temperature is lower than the switching temperature T_{c}.

Since the optical switching temperature of vanadium dioxide is relatively high, various attempts have been made to lower the switching temperature of vanadium dioxide. It has been found that the switching temperature of vanadium dioxide can be reduced by doping Ti, Mo or W. However, the optical switching temperature of vanadium dioxide is still higher than room temperature, which limits the application of vanadium dioxide.

Therefore, there is room for improvement within the art.

### BRIEF DESCRIPTION OF THE FIGURE

Many aspects of the coated article and the method for making the coated article can be better understood with reference to the following drawings. The components in the drawings are not necessarily drawn to scale, the emphasis instead being placed upon clearly illustrating the principles of the coated article and the method. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary embodiment of a coated article;

FIG. 2 is a schematic view of a vacuum sputtering device for processing the coated article in FIG. 1.

### DETAILED DESCRIPTION

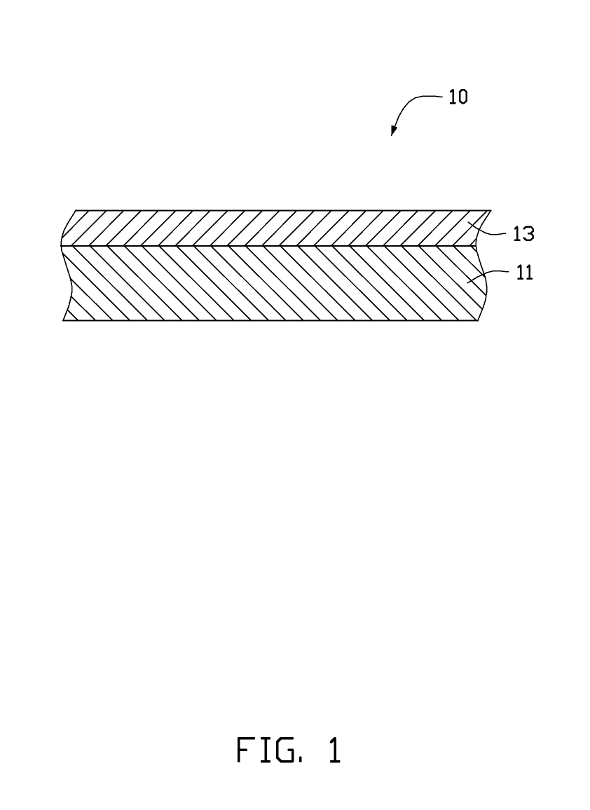

FIG. 1 shows a coated article 10 according to an exemplary embodiment. The coated article 10 includes a substrate 11, and a thermochromic layer 13 formed on a surface of the substrate 11.

The substrate 11 may be made of stainless steel, aluminum alloy, magnesium alloy, glass, ceramic or plastic.

The thermochromic layer 13 is a vanadium dioxide layer co-doped with M and R, wherein M comprises one or more elements selected from a group consisting of titanium (Ti), niobium (Nb), molybdenum (Mo) and tungsten (W), R comprises one or more elements selected from a group consisting of rhodium (Rh), palladium (Pd) and ruthenium (Ru). The various elements that may comprise M and R are in compound form. In this embodiment, M can be molybdenum or tungsten. The atomic ratio of vanadium, M and R in the thermochromic layer 13 is about 17.4-18.8:1-2:0.2-0.6.

The thermochromic layer 13 has a thickness of about 500 nm to about 800 nm. An environmentally friendly vacuum sputtering process may form the thermochromic layer 13.

A exemplary method for making the coated article 10 may include at least the following steps:

A target 23 is provided. The target 23 is made of metal M, metal R and vanadium. The atomic percentage of metal M is from about 10% to about 15%, the atomic percentage of metal R is from about 2% to about 5% and the remaining is vanadium.

The target 23 may be prepared by powder metallurgy with the following steps. mixing metal M powder, metal R powder, and vanadium powder together to form a mixture, wherein the atomic percentage of metal M is from about 10% to about 15%, the atomic percentage of metal R is from about 2% to about 5% and the remaining is vanadium. Hot pressing the mixture into a body; sintering the body at about 1650° C. to about 1950° C. for about 1.5 hours (h) to about 3.0 h; letting the sintered body cool naturally.

The substrate 11 is pretreated. The pre-treating process may include the following steps:

The substrate 11 is positioned in an ultrasonic cleaning device (not shown) with ethanol to be cleaned.

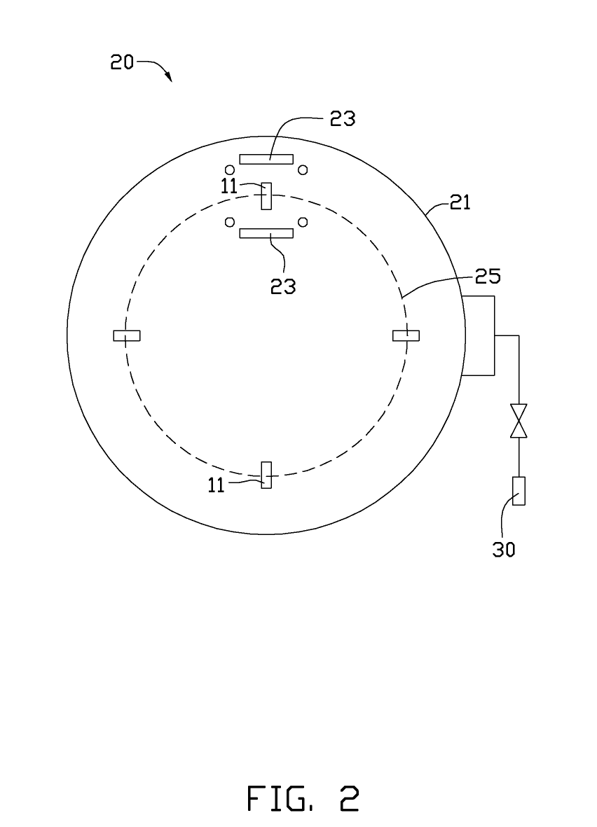

FIG. 2 shows vacuum sputtering device 20 according to an exemplary embodiment. The vacuum sputtering device 20 includes a vacuum chamber 21 and a vacuum pump 30 connected to the vacuum chamber 21. The vacuum pump 30 vacuums the vacuum chamber 21. The vacuum chamber 21 has a pair of targets 23 and a rotary rack (not shown) positioned therein. The rotary rack holds the substrate 11 to revolve along a circular path 25, the substrate 11 also revolves on its own axis while revolving along the circular path 25.

The substrate 11 is plasma cleaned. The substrate 11 may be positioned in the rotary rack of the vacuum chamber 21. The vacuum chamber 21 is then evacuated to 3.0×10⁻⁵ Torr to 5.0×10⁻⁵ Torr. Argon gas (abbreviated as Ar, having a purity of about 99.999%) is used as sputtering gas and is fed into the vacuum chamber 21 at a flow rate of about 200 standard-state cubic centimeters per minute (sccm) to about 400 sccm. A negative bias voltage in a range of −200 V to −300 V is applied to the substrate 11, then high-frequency voltage is produced in the vacuum chamber 21 and the Ar is ionized to plasma. The plasma then strikes the surface of the substrate 11 to clean the surface of the substrate 11. The plasma cleaning of the substrate 11 takes about 10 minutes (min) to about 20 min. The plasma cleaning process will enhance the bond from the substrate 11 and the thermochromic layer 13.

The thermochromic layer 13 is vacuum sputtered on the pretreated substrate 11. Vacuum sputtering of the thermochromic layer 13 is implemented in the vacuum chamber 21. The vacuum chamber 21 is heated to about 100° C. to about 300° C. Oxygen (O₂) is used as reaction gas and is fed into the vacuum chamber 21 at a flow rate of about 50 sccm to 75 sccm. Ar is used as sputtering gas and is fed into the vacuum chamber 21 at a flow rate of about 300 sccm to about 400 sccm. The targets 23 are then powered on and set to from about 2.5 kw to about 3.5 kw. A negative bias voltage is applied to the substrate 11 and the negative bias voltage is about −100 volts (V) to about −200 V. The depositing of the thermochromic layer 13 takes about 30 min to about 60 min.

### EXAMPLES

Experimental examples of the present disclosure are described as followings.

### Example 1

The vacuum sputtering device 20 used in example 1 was a medium frequency magnetron sputtering device (model No. SM-1100H) manufactured by South Innovative Vacuum Technology Co., Ltd. located in Shenzhen, China.

The substrate 11 was made of stainless steel.

Preparing the target 23: titanium powder, molybdenum powder, ruthenium powder and vanadium powder with atomic percentage of 5%, 5%, 3% and 87% respectively were mixed together to form a mixture; the mixture was hot pressed into a body; the body was sintered at 1800° C. for 1.5 h.

Plasma cleaning: Ar was fed into the vacuum chamber 21 at a flow rate of about 400 sccm. A negative bias voltage of −300 V was applied to the substrate 11. The plasma cleaning of the substrate 11 took about 10 min.

Sputtering of the thermochromic layer 13: The vacuum chamber 21 was heated to about 300° C. Oxygen and Ar were fed into the vacuum chamber 21 at a flow rate of about 60 sccm and 300 sccm, respectively. The power of the targets 23 was 3 kw, and a negative bias voltage of −100 V was applied to the substrate 11. The depositing of the thermochromic layer 13 took 60 min. The atomic ratio of vanadium, titanium, molybdenum and ruthenium for the thermochromic layer 13 was 18.8:0.6:0.4:0.2.

The switching temperature of the thermochromic layer 13 in example 1 was from about 27° C. to about 32° C.

### Example 2

The vacuum sputtering device 20 used in example 2 was the same in example 1.

The substrate 11 was made of aluminum alloy.

Preparing the target 23: molybdenum powder, niobium powder, ruthenium powder, rhodium powder and vanadium powder with atomic percentage of 7%, 4%, 2%, 1% and 86% respectively were mixed together to form a mixture; the mixture was hot pressed into a body; the body was sintered at 1800° C. for 1.5 h.

Plasma cleaning: Ar was fed into the vacuum chamber 21 at a flow rate of about 400 sccm. A negative bias voltage of −300 V was applied to the substrate 11. The plasma cleaning of the substrate 11 took about 10 minutes.

Sputtering of the thermochromic layer 13: The vacuum chamber 21 was heated to about 150° C. Oxygen and Ar were fed into the vacuum chamber 21 at a flow rate of about 50 sccm and 300 sccm, respectively. The power of the targets 23 was 3.5 kw, and a negative bias voltage of −150 V was applied to the substrate 11. The depositing of the thermochromic layer 13 took 60 min. The atomic ratio of vanadium, molybdenum, niobium, ruthenium and rhodium for the thermochromic layer 13 was 18.2:1:0.4:0.18:0.2.

The switching temperature of the thermochromic layer 13 in example 2 was from about 10° C. to about 18° C.

### Example 3

The vacuum sputtering device 20 used in example 3 was the same in example 1.

The substrate 11 was made of glass.

Preparing the target 23: molybdenum powder, niobium powder, palladium powder, rhodium powder and vanadium powder with atomic percentage of 8%, 5%, 2%, 2% and 83% respectively were mixed together to form a mixture; the mixture was hot pressed into a body; the body was sintered at 1700° C. for 2 h.

Plasma cleaning: Ar was fed into the vacuum chamber 21 at a flow rate of about 400 sccm. A negative bias voltage of −300 V was applied to the substrate 11. The plasma cleaning of the substrate 11 took about 20 min.

Sputtering of the thermochromic layer 13: The vacuum chamber 21 was heated to about 100° C. Oxygen and Ar were fed into the vacuum chamber 21 at a flow rate of about 65 sccm and 300 sccm, respectively. The power of the targets 23 was 3 kw, and a negative bias voltage of −120 V was applied to the substrate 11. The depositing of the thermochromic layer 13 took 60 min. The atomic ratio of vanadium, molybdenum, niobium, palladium and rhodium for the thermochromic layer 13 was 18.38:0.8:0.4:0.2:0.22.

The switching temperature of the thermochromic layer 13 in example 3 was from about 10° C. to about 20° C.

### Example 4

The vacuum sputtering device 20 used in example 4 was the same in example 1.

The substrate 11 was made of stainless steel.

Preparing the target 23: tungsten powder, titanium powder, rhodium powder and vanadium powder with atomic percentage of 10%, 5%, 5% and 80% respectively were mixed together to form a mixture; the mixture was hot pressed into a body; the body was sintered at 1850° C. for 1.5 h.

Plasma cleaning: Ar was fed into the vacuum chamber 21 at a flow rate of about 400 sccm. A negative bias voltage of −300 V was applied to the substrate 11. The plasma cleaning of the substrate 11 took about 10 min.

Sputtering of the thermochromic layer 13: The vacuum chamber 21 was heated to about 200° C. Oxygen and Ar were fed into the vacuum chamber 21 at a flow rate of about 60 sccm and 300 sccm respectively. The power of the targets 23 was 3.5 kw, and a negative bias voltage of −150 V was applied to the substrate 11. The depositing of the thermochromic layer 13 took 45 min. The atomic ratio of vanadium, tungsten, titanium and rhodium for the thermochromic layer 13 was 18.1:0.4:0.3:0.28.

The switching temperature of the thermochromic layer 13 in example 4 was from about 15° C. to about 20° C.

### Example 5

The vacuum sputtering device 20 used in example 4 was the same in example 1.

The substrate 11 was made of glass.

Preparing the target 23: tungsten powder, niobium powder, titanium powder, palladium powder, ruthenium powder and vanadium powder with atomic percentage of 8%, 3%, 3%, 2%, 3% and 80% respectively were mixed together to form a mixture; the mixture was hot pressed into a body; the body was sintered at 1850° C. for 2 h.

Plasma cleaning: Ar was fed into the vacuum chamber 21 at a flow rate of about 400 sccm. A negative bias voltage of −300 V was applied to the substrate 11. The plasma cleaning of the substrate 11 took about 10 min.

Sputtering of the thermochromic layer 13: The vacuum chamber 21 was heated to about 150° C. Oxygen and Ar were fed into the vacuum chamber 21 at a flow rate of about 65 sccm and 300 sccm, respectively. The power of the targets 23 was 3 kw, and a negative bias voltage of −120 V was applied to the substrate 11. The depositing of the thermochromic layer 13 took 60 min. The atomic ratio of vanadium, tungsten, niobium, titanium, palladium and ruthenium for the thermochromic layer 13 was 18.18:1:0.2:0.3:0.12:0.2.

The switching temperature of the thermochromic layer 13 in example 5 was from about 15° C. to about 25° C.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate; and
a thermochromic layer formed on the substrate;
wherein the thermochromic layer is a vanadium dioxide layer co-doped with M and R, M comprises one or more elements selected from a group consisting of titanium, niobium, molybdenum and tungsten, R comprises one or more elements selected from a group consisting of rhodium, palladium and ruthenium.

2. The coated article as claimed in claim 1, wherein the atomic ratio of vanadium, M and R for the thermochromic layer is about 17.4-18.8:1-2:0.2-0.6.

3. The coated article as claimed in claim 2, wherein the substrate is made of stainless steel, aluminum alloy, magnesium alloy, glass, ceramic or plastic.

4. The coated article as claimed in claim 2, wherein the thermochromic layer is made by magnetron sputtering process.

5. The coated article as claimed in claim 1, wherein the thermochromic layer has a thickness of about 500 nm to about 800 nm.

6. A method for making a coated article, comprising:
providing a substrate; and
forming an thermochromic layer on the substrate by magnetron sputtering process, the thermochromic layer is a vanadium dioxide layer co-doped with M and R, wherein M comprises one or more elements selected from a group consisting of titanium, niobium, molybdenum and tungsten, R comprises one or more elements selected from a group consisting of rhodium, palladium and ruthenium; the forming process uses targets which are made of metal M, metal R and vanadium, and the atomic percentage of metal M is from about 10% to about 15%, the atomic percentage of metal R is from about 2% to about 5% and the remaining is vanadium.

7. The method as claimed in claim 6, wherein magnetron sputtering the thermochromic layer uses oxygen as reaction gas and oxygen has a flow rate of about 50 sccm to about 75 sccm, uses argon gas as sputtering gas and argon gas has a flow rate of about 300 sccm to about 400 sccm; magnetron sputtering the thermochromic layer is at a temperature of about 100° C. to about 300° C., the power of the targets is about 2.5 kw to about 3.5 kw, a negative bias voltage of about −100V to about −200V is applied to the substrate, vacuum sputtering the thermochromic layer takes about 30 min to about 60 min.

8. The method as claimed in claim 6, wherein the target is prepared by powder metallurgy with the following steps: mixing metal M powder, metal R powder, and vanadium powder together to form a mixture, wherein the atomic percentage of metal M is from about 10% to about 15%, the atomic percentage of metal R is from about 2% to about 5% and the remaining is vanadium; hot pressing the mixture into a body; sintering the body at about 1650° C. to about 1950° C. for about 1.5 h to about 3.0 h.

9. The method as claimed in claim 6, wherein the substrate is made of stainless steel, aluminum alloy, magnesium alloy, glass, ceramic or plastic.

10. The method as claimed in claim 6, wherein the thermochromic layer has a thickness of about 500 nm to about 800 nm.
